(19) United States
(12) Patent Application Publication
(10) Pub. No.: US 2020/0312677 A1
(43) Pub. Date: Oct. 1, 2020

(54) SUBSTRATE PROCESSING APPARATUS

(71) Applicant: Tokyo Electron Limited, Tokyo (JP)

(72) Inventors: Yoshihiro TAKEZAWA, Nirasaki City (JP); Keita KUMAGAI, Nirasaki City (JP); Keisuke FUJITA, Nirasaki City (JP); Hiroyuki HAYASHI, Nirasaki City (JP); Daisuke Suzuki, Nirasaki City (JP); Rui KANEMURA, Nirasaki City (JP); Sena FUJITA, Nirasaki City (JP)

(73) Assignee: TOKYO ELECTRON LIMITED, Tokyo (JP)

(21) Appl. No.: 16/821,133

(22) Filed: Mar. 17, 2020

(30) Foreign Application Priority Data
Mar. 29, 2019 (JP) 2019-067832

(51) Int. Cl. H01L 21/67; H01L 21/04; H01L 21/768

(52) U.S. Cl. CPC H01L 21/6708; H01L 21/76856; H01L 21/042

(57) ABSTRACT

A substrate processing apparatus includes a processing container configured to accommodate a plurality of substrates therein, a gas supply configured to supply a first raw material gas of a compound containing Si or Ge and H and a second raw material gas of a compound containing Si or Ge and a halogen element into the processing container; and an exhauster configured to evacuate an inside of the processing container, wherein the gas supply has a dispersion nozzle provided with a plurality of gas holes for discharging the first raw material gas and the second raw material gas, and the substrate processing apparatus further comprises a heater configured to heat the first raw material gas and the second raw material gas in the dispersion nozzle.

### CROSS-REFERENCE TO RELATED APPLICATION

This application is based upon and claims the benefit of priority from Japanese Patent Application No. 2019-067832, filed on Mar. 29, 2019, the entire contents of which are incorporated herein by reference.

### TECHNICAL FIELD

The present disclosure relates to a substrate processing apparatus.

### BACKGROUND

As a process technology for manufacturing a semiconductor device, there is disclosed a technology in which a silicon film or the like is formed by a substrate processing apparatus on a substrate having an uneven surface, to fill recess portions formed on the surface of the substrate with the silicon film or the like.

### PRIOR ART DOCUMENT

### Patent Document

Japanese Laid-Open Patent Publication No. 2017-152426

### SUMMARY

According to embodiments of the present disclosure, there is provided a substrate processing apparatus including a processing container configured to accommodate a plurality of substrates therein, a gas supply configured to supply a first raw material gas of a compound containing Si or Ge and H and a second raw material gas of a compound containing Si or Ge and a halogen element into the processing container; and an exhauster configured to evacuate an inside of the processing container, wherein the gas supply has a dispersion nozzle provided with a plurality of gas holes for discharging the first raw material gas and the second raw material gas, and the substrate processing apparatus further comprises a heater configured to heat the first raw material gas and the second raw material gas in the dispersion nozzle.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram of raw material gases and characteristics when a silicon film is formed by a CVD method.

FIG. 2 is a view illustrating a configuration of a substrate processing apparatus in an embodiment.

FIG. 3 is a cross-sectional view of a processing container of the substrate processing apparatus in the present embodiment.

FIG. 4 is a view illustrating a configuration of another substrate processing apparatus in the present embodiment.

FIG. 5 is a cross-sectional view of a processing container of another substrate processing apparatus in the present embodiment.

FIG. 6 is a process view of a method for forming a semiconductor film in the present embodiment.

FIG. 7 is a process view of a method for forming a semiconductor film in the present embodiment.

FIG. 8 is an explanatory diagram of a method for forming a semiconductor film in the present embodiment

FIG. 9 is a view illustrating a configuration of a substrate processing apparatus used for comparison.

FIG. 10 is an explanatory diagram of a silicon film formed by the substrate processing apparatus shown in FIG. 9.

FIG. 11 is an explanatory diagram of a silicon film formed by the substrate processing apparatus in the present embodiment.

FIG. 12 is a process view of a modification of the method for forming a semiconductor film in the present embodiment.

FIG. 13 is a process view of a modification of the method for forming a semiconductor film in the present embodiment.

FIG. 14 is a process view of a modification of the method for forming a semiconductor film in the present embodiment.

FIG. 15 is an explanatory diagram of a modification of the method for forming a semiconductor film in the present embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An embodiment will be described below. The same members or the like will be denoted by the same reference numerals and redundant descriptions thereof will be omitted. In the present application, an X1-X2 direction, a Y1-Y2 direction, and a Z1-Z2 direction are directions orthogonal to each other. In addition, a plane including the X1-X2 direction and the Y1-Y2 direction will be referred to as an XY plane, a plane including the Y1-Y2 direction and the Z1-Z2 direction will be referred to as a YZ plane, and a plane including the Z1-Z2 direction and the X1-X2 direction will be referred to as a ZX plane.

### (Semiconductor Film Formation)

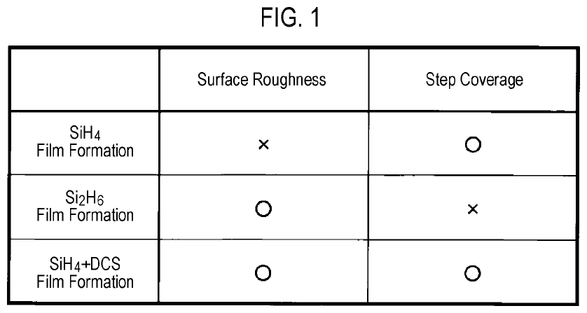

First, a case where a silicon film is formed by chemical vapor deposition (CVD method) will be described. Methods of forming an amorphous silicon film by CVD method include a method using monosilane (SiH₄) as a raw material gas and a method using disilane (Si₂H₆) as a raw material gas. As depicted in FIG. 1, when an amorphous silicon film is formed by CVD method using monosilane as a raw material gas on a substrate having an uneven surface, the formed amorphous silicon film is good in step coverage, but is not very good in surface roughness. In addition, when an amorphous silicon film is formed by CVD method using disilane as a raw material gas on the substrate having an uneven substrate, the formed amorphous silicon film is good in surface roughness, but is not very good in step coverage.

That is, when an amorphous silicon film is formed by CVD method, it is difficult to obtain a silicon film which is good in both surface roughness and step coverage regardless of whether monosilane or disilane is used as a raw material gas.

Accordingly, as a result of a study, the inventor conceived the idea of simultaneously supplying monosilane and dichlorosilane (SiH₂Cl₂) to form a film. This makes it possible to obtain an amorphous silicon film, which is good in both surface roughness and step coverage. When forming an amorphous silicon film by simultaneously supplying monosilane and dichlorosilane to a plurality of substrates, the in-plane uniformity in film thickness is likely to vary between the substrates since two raw material gases are used. As a result of further study, the inventor has come to conceive a substrate processing apparatus capable of forming a film that is good in both surface roughness and step coverage, and capable of suppressing variations in the in-plane uniformity of film thickness between substrates. Hereinafter, the conceived substrate processing apparatus will be described as the present embodiment.

### [Configuration of Substrate Processing Apparatus]

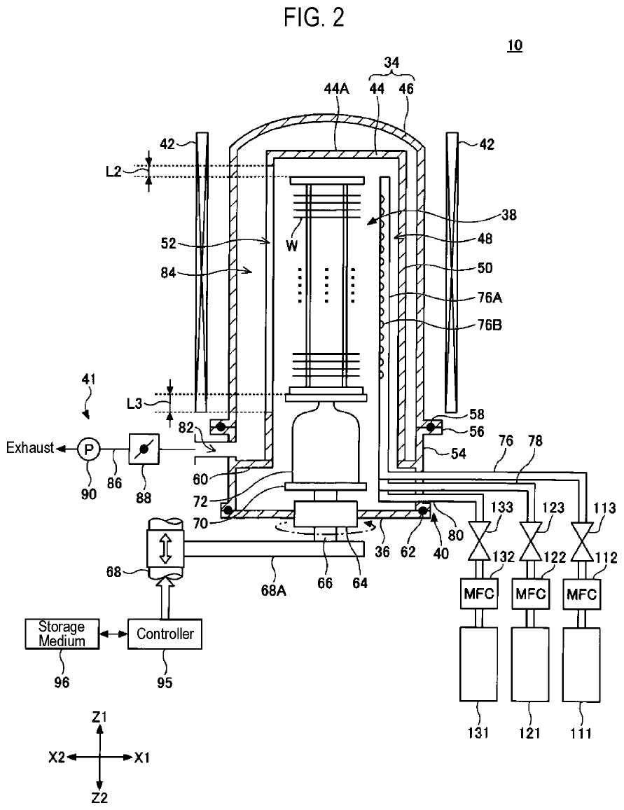

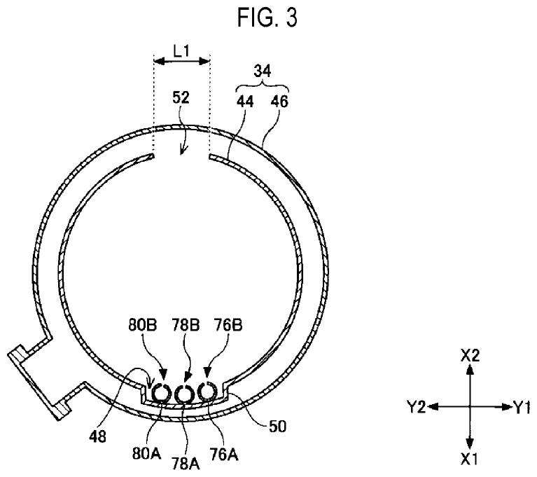

The substrate processing apparatus of the present embodiment will be described with reference to FIGS. 2 and 3. The substrate processing apparatus of the present embodiment is a batch-type vertical substrate processing apparatus capable of simultaneously forming films on a plurality of substrates.

As illustrated in FIG. 2, a substrate processing apparatus 10 includes a processing container 34 configured to accommodate therein semiconductor wafers W as substrates, and a lid 36 configured to close an opening at a lower end of the processing container 34 on the Z2 side. In addition, the substrate processing apparatus 10 includes a wafer boat 38, which is capable of being accommodated in the processing container 34 and serves as a substrate holder for holding a plurality of semiconductor wafers W at predetermined intervals, a gas supply 40 configured to supply gas into the processing container 34, and an exhauster 41 configured to exhaust gas in the processing container 34. A heater 42 configured to heat an inside of the processing container 34 is provided outside the processing container 34.

The processing container 34 includes a cylindrical inner tube 44 having a lower open end on the Z2 side and a ceiling 44A on the Z1 side, and a cylindrical outer tube 46 having a lower open end on the Z2 side and a ceiling on the Z1 side and covering an outside of the inner tube 44. The inner tube 44 and the outer tube 46 are formed of a heat-resistant material such as quartz, and are coaxially arranged along the Z1-Z2 direction so as to form a double tube structure.

The ceiling 44A of the inner tube 44 is, for example, flat. Inside the inner tube 44, a nozzle accommodation part 48 for accommodating therein a gas supply tube is formed along the Z1-Z2 direction. For example, as illustrated in FIG. 3, a part of a side wall of the inner tube 44 is formed to have a convex portion 50 that protrudes outward in the X1 direction, and an inside of the formed convex portion 50 may be used as the nozzle accommodation part 48. In a side wall of the inner tube 44 on the X2 side facing the nozzle accommodation part 48A, a rectangular opening 52 having a width L1 is formed along the Z1-Z2 direction.

The opening 52 is an exhaust port for evacuating the inside of the inner tube 44. The length of the opening 52 in the Z1-Z2 direction is equal to or longer than the length of the wafer boat 38. That is, the upper end on the Z1 side, the opening 52 is formed longer than the position corresponding to the upper end of the wafer boat 38 toward Z1 side and, at the lower end on the Z2 side, the opening 52 is formed longer than the position corresponding to the lower end of the wafer boat 38 toward Z2 side. Specifically, as illustrated in FIG. 2, the length L2 in the Z1-Z2 direction between the upper end of the wafer boat 38 and the upper end of the opening 52 is about 0 mm to 5 mm. The length L3 in the Z1-Z2 direction between the lower end of the wafer boat 38 and the lower end of the opening 52 is about 0 mm to 350 mm.

The lower end of the processing container 34 on the Z2 side is supported by a cylindrical manifold 54 formed of, for example, stainless steel. A flange 56 is formed at the upper end of the manifold 54 on the Z1 side, and the lower end of the outer tube 46 on the Z2 side is connected to the flange 56. A seal member 58 such as an O-ring is provided between the flange 56 and the outer tube 46, and the flange 56 and the outer tube 46 are connected to each other via the seal member 58. Herein, a region surrounded by the processing container 34, the manifold 54, and the lid 36 inside the processing container 34 may be referred to as an inside of the processing container.

An annular support portion 60 is provided on an inner wall of the manifold 54 on the Z1 side, which is the upper portion of the manifold 54, and the lower end of the inner tube 44 on the Z2 side is installed on the support portion 60 so as to be supported thereon. The lid 36 is installed in the opening at the lower end of the manifold 54 on the Z2 side via a seal member 62 such as an O-ring, thereby hermetically blocking the opening of the processing container 34 at the lower end on the Z2 side, that is, the opening of the manifold 54. The lid 36 is formed of, for example, stainless steel.

At the center of the lid 36, a rotary shaft 66 is provided through a magnetic fluid seal 64. A lower portion of the rotary shaft 66 on the Z2 side is rotatably supported on an arm 68A of an elevator 68 configured as a boat elevator.

A rotary plate 70 is provided at the upper end of the rotary shaft 66 on the Z1 side, and the wafer boat 38 that holds the semiconductor wafers W is placed on the rotary plate 70 via a quartz heat-retaining stage 72. Accordingly, by moving the arm 68A up and down by the elevator 68, the lid 36 and the wafer boat 38 move up and down integrally, so that the wafer boat 38 can be put in and out of the processing container 34.

The gas supply 40 is provided in the manifold 54 and may supply a first raw material gas, a second raw material gas, a purge gas, and the like into the inner tube 44. The gas supply 40 has a plurality of (e.g., three) gas supply pipes 76, 78, and 80 made of quartz. The gas supply pipes 76, 78, and 80 have dispersion nozzles 76A, 78A, and 80A, respectively, along the Z1-Z2 direction in the inner tube 44. An end portion of each of the gas supply pipes 76, 78, and 80 on the Z2 side is bent into an L shape to the X1 side, and penetrates through the manifold 54 to be supported thereon.

As illustrated in FIG. 3, the gas supply pipes 76, 78, and 80 are installed in the nozzle accommodation part 48 of the inner tube 44 along the circumferential direction. In the gas supply pipes 76, 78, and 80, a plurality of gas holes 76B, 78B, and 80B are formed at predetermined intervals in the dispersion nozzle 76A, 78A, and 80A, respectively, provided in the inner tube 44, and gases are discharged in a substantially horizontal direction from the gas holes 76B, 78B, and 80B, respectively. The predetermined intervals are the same as, for example, the intervals between the semiconductor wafers W supported by the wafer boat 38. The positions of the gas holes 76B, 78B, and 80B in the dispersion nozzle 76A, 78A, and 80A, respectively, in the Z1-Z2 direction are located in the middle between adjacent semiconductor wafers W in the Z1-Z2 direction, so that it is possible to efficiently supply each gas to the spaces between the semiconductor wafers W. However, the predetermined intervals between the respective gas holes 76B, 78B, and 80B are not limited to the above. A gas hole may be provided for a plurality of semiconductor wafers W.

The positions of the respective gas holes 76B, 78B, and 80B are not limited to intermediate positions between adjacent semiconductor wafers W, but may be provided at arbitrary positions such as the same heights as the semiconductor wafers W. In addition, the directions of the respective gas holes 76B, 78B, and 80B may be provided in arbitrary directions, for example, toward the centers of the semiconductor wafers W, toward the outer peripheries of the semiconductor wafers W, or toward the inner tube 44.

A cylindrical heater 42 is provided near the outer periphery of the outer tube 46 so as to surround the outer tube 46. The semiconductor wafers W accommodated in the processing container 34 and the gases in the dispersion nozzles 76A and 78A of the gas supply pipes 76 and 78 may be heated using the heater 42.

In the present embodiment, the first raw material gas is supplied from the gas supply pipe 76, the second raw material gas is supplied from the gas supply pipe 78, and the purge gas is supplied from the gas supply pipe 80. A first raw material gas supply source 111 is connected to the gas supply pipe 76 via a flow rate controller 112 and an opening/closing valve 113, and a second raw material gas supply source 121 is connected to the gas supply pipe 78 via a flow rate controller 122 and an opening/closing valve 123. In addition, a purge gas supply source 131 is connected to the gas supply pipe 80 via a flow rate controller 132 and an opening/closing valve 133.

Specifically, from the first raw material gas supply source 111, monosilane, which is the first raw material gas at a required flow rate, is supplied to the gas supply pipe 76 through the opening/closing valve 113 under the control of the flow rate controller 112 such as a mass flow controller. Then, the gas is discharged into the inner tube 44 of the processing container 34 from the gas holes 76B in the dispersion nozzle 76A of the gas supply pipe 76. From the second raw material gas supply source 121, dichlorosilane, which is the second raw material gas at a required flow rate, is supplied to the gas supply pipe 78 through the opening/closing valve 123 under the control of the flow rate controller 122 such as a mass flow controller. Then, the gas is discharged into the inner tube 44 of the processing container 34 from the gas holes 78B in the dispersion nozzle 78A of the gas supply pipe 78.

Monosilane, which is the first raw material gas present in the gas supply pipe 76 in the inner tube 44, and dichlorosilane, which is the second raw material gas present in the gas supply pipe 78, are heated by the heater 42. When the heating of monosilane as the first raw material gas and dichlorosilane as the second raw material gas is insufficient, the activation states of the raw material gases discharged toward the semiconductor wafers W differ from each other between the substrates, and the in-plane uniformity in the silicon film to be formed varies between the substrates. In the present embodiment, since the dispersion nozzles having a longer residence time until the gases are discharged to the semiconductor wafers W after being supplied into the processing container are used, the monosilane as the first raw material gas and the dichlorosilane as the second raw material gas in the dispersion nozzles 76A and 78A are sufficiently heated by heating the dispersion nozzle 76A and 78A in the inner tube 44 by the heater 42. Accordingly, when being discharged from the gas holes 76B and 78B, the first raw material gas and the second raw material gas can be activated substantially uniformly, so that the in-plane uniformity in the film thickness of the silicon film to be formed can be improved between the substrates.

An exhaust port 82 is provided in the upper side wall of the manifold 54 on the Z1 side and above the support portion 60, and the gas inside the inner tube 44 is exhausted from the opening 52 and through the space 84 between the inner tube 44 and the outer tube 46. The exhauster 41 is connected to the exhaust port 82. The exhauster 41 is provided with a pressure adjustment valve 88, an exhaust passage 86, and a vacuum pump 90 in this order from the exhaust port 82, and is capable of evacuating the inside of the processing container 34.

In the present embodiment, a plurality of semiconductor wafers W are provided in the inner tube 44 in the Z1-Z2 direction, which is perpendicular to the wafer surfaces, such that the wafer surfaces serving as the substrate surfaces are parallel to the XY plane. The monosilane as the first raw material gas and the dichlorosilane as the second raw material gas are discharged between the semiconductor wafers W from the gas holes 76B and 78B of the dispersion nozzles 76A and 78A. The discharged raw material gases pass through the spaces between the semiconductor wafers W so as to form a silicon film, but a gas that does not contribute to the formation of the silicon film flows out of the inner tube 44 from the opening 52 on the X2 side, passes through the space 84 between the inner tube 44 and the outer tube 46, and is exhausted from the exhaust port 82.

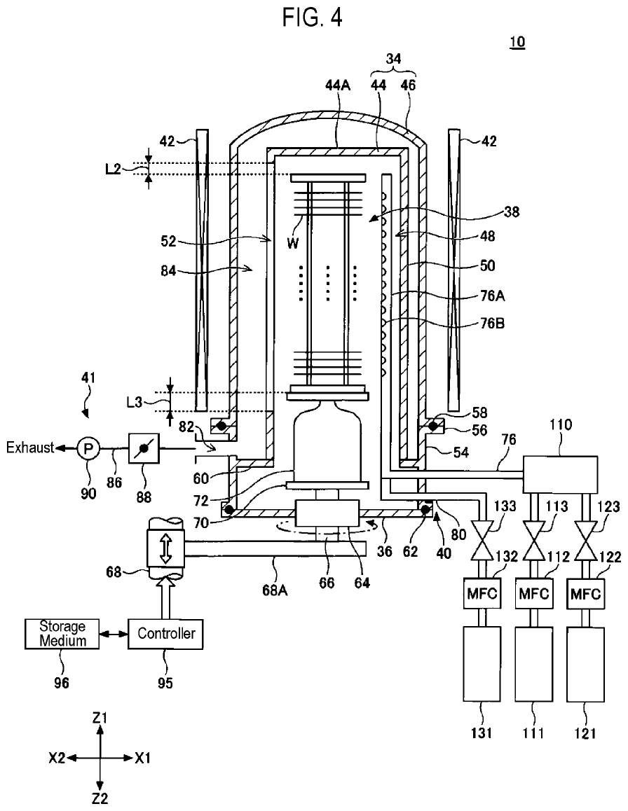

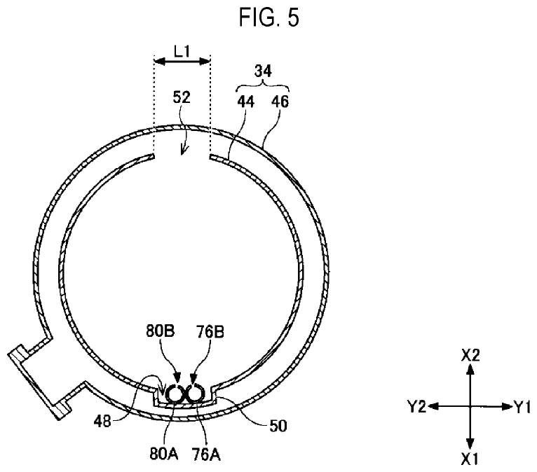

Next, another substrate processing apparatus in the present embodiment will be described with reference to FIGS. 4 and 5. In the above description, an example in which monosilane as the first raw material gas and dichlorosilane as the second raw material gas are supplied using separate gas supply pipes is illustrated. However, in the example illustrated in FIGS. 4 and 5, each raw material gas is supplied from the same gas supply pipe. In addition, a raw material gas mixer 110 may be provided either outside or inside the processing container 34, but is preferably provided outside the processing container 34 as illustrated in FIGS. 4 and 5.

A gas mixture of the first raw material gas and the second raw material gas is supplied from a gas supply pipe 76, and a purge gas is supplied from a gas supply pipe 80. In addition, the raw material gas mixer 110 configured to mix the first raw material gas and the second raw material gas is provided. Accordingly, a first raw material gas supply source 111 is connected to the raw material gas mixer 110 via a flow rate controller 112 and an opening/closing valve 113, and a second raw material gas supply source 121 is connected to the raw material gas mixer 110 via a flow rate controller 122 and an opening/closing valve 123. The raw material gas mixer 110 may take any form as long as the two raw material gases are merged on the downstream side of the opening/closing valve 113 and the opening/closing valve 123, and is not limited in shape and structure. Further, a purge gas supply source 131 is connected to the gas supply pipe 80 via a flow rate controller 132 and an opening/closing valve 133.

Specifically, from the first raw material gas supply source 111, monosilane, which is the first raw material gas at a required flow rate, is supplied to the raw material gas mixer 110 through the opening/closing valve 113 under the control of the flow rate controller 112 such as a mass flow controller. From the second raw material gas supply source 121, dichlorosilane, which is the second raw material gas at a required flow rate, is supplied to the raw material gas mixer 110 through the opening/closing valve 123 under the control of the flow rate controller 122 such as a mass flow controller. In the raw material gas mixer 110, the monosilane as the first raw material gas and the dichlorosilane as the second raw material gas are mixed, and the mixture gas is supplied from the gas holes 76B in the dispersion nozzle 76A of the gas supply pipe 76 to the inside of the inner tube 44 of the processing container 34.

As described above, since the first raw material gas and the second raw material gas are mixed in the raw material gas mixer 110, the ratio between the first raw material gas and the second raw material gas, which are discharged from the gas holes 76B of the dispersion nozzle 76A, can be made uniform. This makes it possible to suppress the occurrence of variation in the in-plane uniformity in the film thickness of the silicon film formed between the substrates. When the ratio between the monosilane as the first raw material gas and the dichlorosilane as the second raw material gas, which are discharged into the inner tube 44, is not uniform, the in-plane uniformity in the film thickness of the silicon film to be formed is likely to vary.

An exhaust port 82 is provided in the upper side wall of the manifold 54 on the Z1 side and above the support portion 60, and the gas inside the inner tube 44 is exhausted from the opening 52 and through the space 84 between the inner tube 44 and the outer tube 46. The exhauster 41 is connected to the exhaust port 82. The exhauster 41 is provided with a pressure adjustment valve 88, an exhaust passage 86, and a vacuum pump 90 in this order from the exhaust port 82, and is capable of evacuating the inside of the processing container 34.

In the present embodiment, a plurality of semiconductor wafers W are provided in the inner tube 44 in the Z1-Z2 direction, which is perpendicular to the wafer surfaces, such that the wafer surfaces serving as the substrate surfaces are parallel to the XY plane. The mixture gas of monosilane as the first raw material gas and dichlorosilane as the second raw material gas is discharged to the spaces between the semiconductor wafers W from the gas holes 76B of the dispersion nozzle 76A. The discharged mixture gas passes through the spaces between the semiconductor wafers W so as to form a silicon film, but a gas that does not contribute to the formation of the silicon film flows out of the inner tube 44 from the opening 52 on the X2 side, passes through the space 84 between the inner tube 44 and the outer tube 46, and is exhausted from the exhaust port 82.

The overall operation of the substrate processing apparatus 10 is controlled by a controller 95 such as a computer. A computer program that performs the overall operation of the substrate processing apparatus 10 may be stored in a storage medium 96. The storage medium 96 may be, for example, a flexible disk, a compact disc, a hard disk, a flash memory, a DVD, or the like.

In the present embodiment, the controller 95 controls the flow rate controller 112, the opening/closing valve 113, the flow rate controller 122, the opening/closing valve 123, the flow rate controller 132, the opening/closing valve 133, the heater 42, and the like.

### (Semiconductor Film Formation Method)

Next, a method for forming a silicon film as a semiconductor film on a semiconductor wafer W using the substrate processing apparatus 10 according to the present embodiment will be described. First, the wafer boat 38 holding a plurality of semiconductor wafers W is carried into the processing container 34 by the elevator 68, the opening at the lower end of the processing container 34 is hermetically blocked and sealed by the lid 36, and the processing container 34 is evacuated by the exhauster 41 until the pressure inside the processing container 34 reaches a predetermined pressure. Thereafter, the semiconductor wafers W in the processing container 34 and the mixture gas in the gas supply pipe 76 are heated by the heater 42, and the mixture gas of the first raw material gas and the second raw material gas is supplied from the gas holes 76B in the dispersion nozzle 76A of the gas supply pipe 76 to form a silicon film. At this time, by rotating the wafer boat 38, the semiconductor wafers W are rotated so as to form a silicon film thereon.

The first raw material gas is a compound gas of silicon (Si) and hydrogen (H), for example, SiH₄, Si₂H₆, or the like.

The second raw material gas is a gas of a compound of Si and a halogen element. For example, the second raw material gas may be a fluorine-containing silicon gas such as SiF₄, SiHF₃, SiH₂F₂, SiH₃F, or the like, a chlorine-containing silicon gas such as SiCl₄, SiHCl₃, SiH₂Cl₂ (DCS), SiH₃Cl, Si₂Cl₆, or the like, or a bromine-containing gas such as SiBr₄, SiHBr₃, SiH₂Br₂, SiH₃Br, or the like. In the present embodiment, as the second raw material gas, a compound gas containing silicon and chlorine (Cl) is preferable. In addition, SiCl₄, SiHCl₃, SiH₂Cl₂, SiH₃Cl, Si₂Cl₆, or the like is preferable.

Since it is more preferable that the first raw material gas is SiH₄ and the second raw material gas is SiH₂Cl₂, such a case is described in the present embodiment.

The silicon film may be, for example, a non-doped film or a doped film. The dopant of the doped film may be, for example, phosphorus (P), boron (B), arsenic (As), oxygen (O), or carbon (C).

Descriptions will be made in more detail with reference to FIGS. 6 to 8. First, as illustrated in FIG. 6, a semiconductor wafer W having a silicon oxide film (a SiO₂ film) 202 formed on a surface of a silicon substrate 201 is provided. The silicon oxide film 202 is formed by thermally oxidizing silicon on the surface of the silicon substrate 201, but may be formed by sputtering, CVD method, or the like.

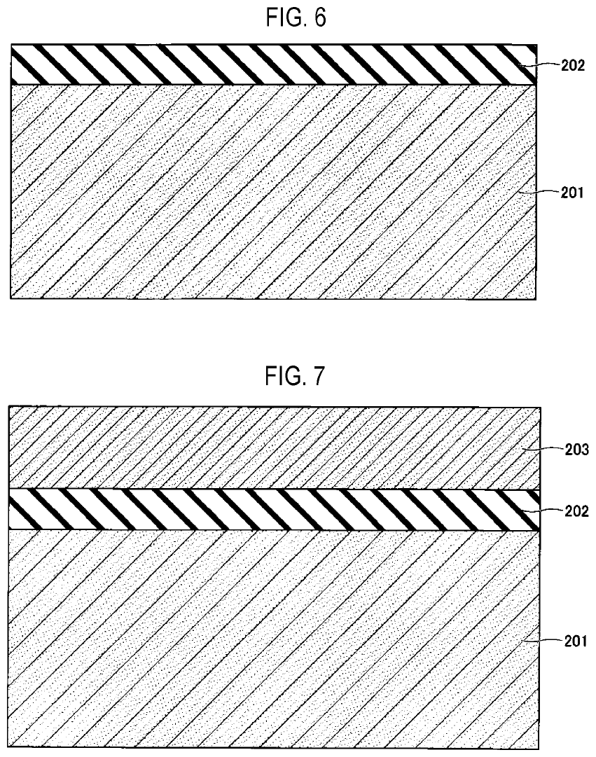

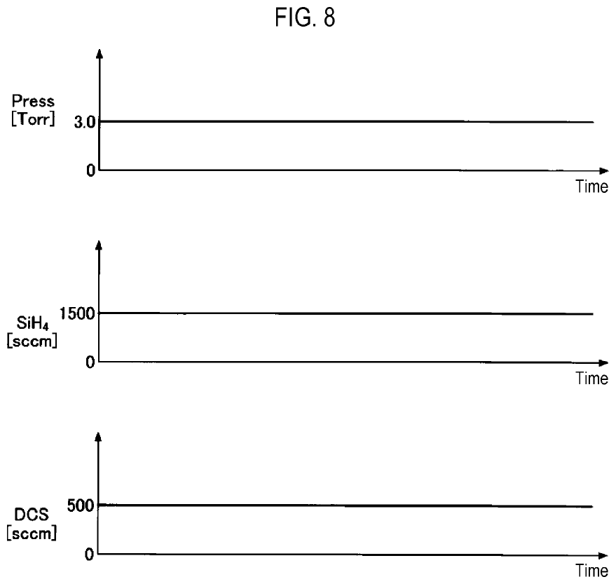

Next, as illustrated in FIG. 7, a silicon film 203 is formed on the silicon oxide film 202 using the substrate processing apparatus 10 in the present embodiment. Specifically, as illustrated in FIG. 8, the silicon film 203 is formed by simultaneously supplying monosilane (SiH₄) as the first raw material gas at 1,500 sccm and dichlorosilane (DCS) as the second raw material gas at 500 sccm. At this time, the gas pressure inside the processing container 34 is set to 3.0 Torr.

Further, the surface of the silicon substrate 201 may not be flat, and for example, recesses such as a trench, a hole, and the like may be formed on the surface. In addition, instead of the silicon oxide film 202, a silicon nitride film (a SiN film) may be formed on the surface of the silicon substrate 201.

In addition, before supplying the mixture gas of the first raw material gas and the second raw material gas, an aminosilane-based gas may be supplied onto the silicon oxide film 202 so as to form a seed layer. The aminosilane-based gas may be, for example, diisopropylamino silane (DIPAS), tris(dimethylamino)silane (3DMAS), or bis(tertiarybutylamino)silane (BTBAS).

Although the case where a silicon film is formed has been described above, the present embodiment is not limited thereto. The method for forming a semiconductor film may be, for example, a case where a germanium film or a silicon germanium film is formed. The germanium film and the silicon germanium film may be, for example, a non-doped film or a doped film.

Accordingly, in the present embodiment, it is also possible to use a germanium raw material gas as the first raw material gas. The germanium raw material gas may be, for example, GeH₄, Ge₂H₆, or Ge₃H₈. As the second raw material gas, a halogen-containing germanium gas may be used. The halogen-containing germanium gas may be, for example, a fluorine-containing germanium gas such as GeF₄, GeHF₃, GeH₂F₂, GeH₃F, or the like, a chlorine-containing germanium gas such as GeCl₄, GeHCl₃, GeH₂Cl₂, GeH₃Cl, or the like, or a bromine-containing germanium gas such as GeBr₄, GeHBr₃, GeH₂Br₂, GeH₃Br, or the like. Furthermore, in this case, for example, an aminogermane-based gas may be used instead of the aminosilane-based gas. The aminogermane-based gas may be, for example, dimethylamino germane (DMAG), diethylamino germane (DEAG), bis(dimethylamino)germane (BDMAG), bis(diethylamino)germane (BDEAG), or tris(dimethylamino)germane (3DMAG).

### (In-Plane Uniformity)

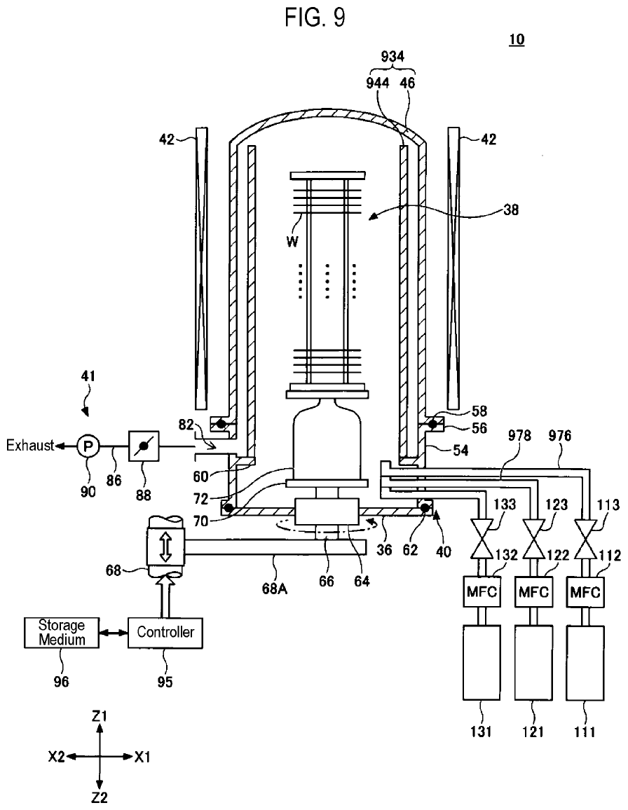

Next, in-plane uniformity of a film thickness between substrates will be described in a silicon film formed by the above-described film formation method using the substrate processing apparatus in the present embodiment and a silicon film formed using the substrate processing apparatus having the configuration illustrated in FIG. 9. The value of in-plane uniformity of a film thickness is calculated from (MAX−MIN)/AVE×(½)×100, where MAX is the largest film thickness of a silicon film formed on a substrate, MIN is the smallest film thickness, and AVE is the average film thickness.

The substrate processing apparatus illustrated in FIG. 9 has a configuration in which gas supply pipes are not provided with a dispersion nozzle and a raw material gas mixer is not provided. In the substrate processing apparatus having this configuration, gas supply pipes 976 and 978 are provided, and monosilane as the first raw material gas is supplied into a processing container 934 through the gas supply pipe 976, and dichlorosilane as the second raw material gas is supplied into the processing container 934 through the gas supply pipe 978. In the substrate processing apparatus illustrated in FIG. 9, an inner tube 944 of the processing container 934 does not have a ceiling.

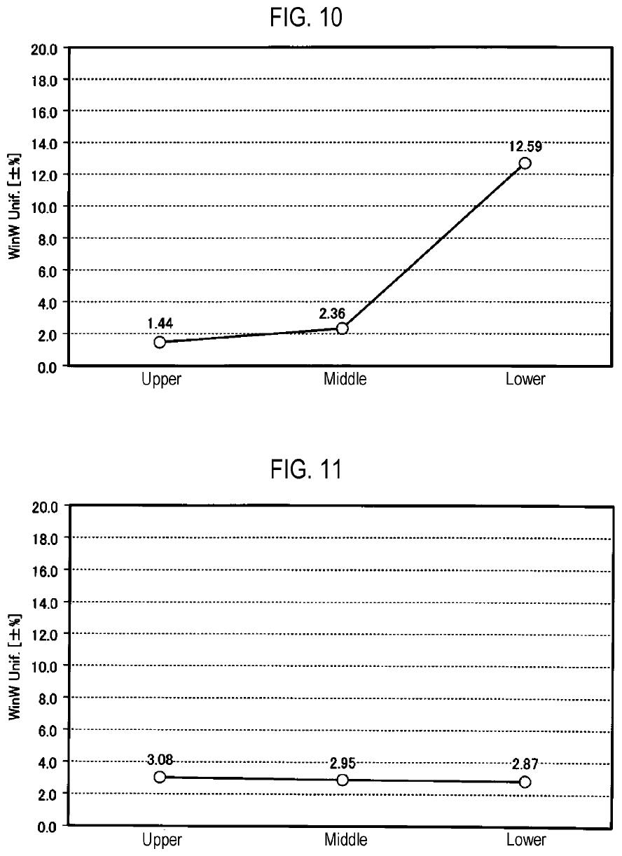

FIG. 10 shows results of measuring the in-plane uniformity of silicon films when the silicon films were formed using the substrate processing apparatus having the configuration illustrated in FIG. 9. “Upper”, “Middle”, and “Lower” indicated on the horizontal axis in FIG. 10 indicate the positions of the semiconductor wafers W in the processing container 934. “Upper” indicates semiconductor wafers W installed on the Z1 side, “Lower” indicates semiconductor wafers W installed on the Z2 side, and “Middle” indicates semiconductor wafers W installed at an intermediate position therebetween. As shown in FIG. 10, in the substrate processing apparatus having the configuration illustrated in FIG. 9, the in-plane uniformity of silicon films formed on semiconductor wafers W is ±1.44% at “Upper” and ±2.36% at “Middle” and thus low, but the in-plane uniformity at “Lower” rises sharply to be ±12.59%. Accordingly, when silicon films are formed in the same batch, the semiconductor wafers installed at the upper portion and the middle portion of the processing container 934 may be used for a subsequent process, but the semiconductor wafers installed at the lower portion are poor in in-plane uniformity and thus may not be used in a subsequent process. Thus, this leads to an increase in the cost of manufacturing semiconductor devices.

Next, FIG. 11 shows results of measuring the in-plane uniformity of silicon films when the silicon films were formed using the substrate processing apparatus according to the present embodiment. “Upper”, “Middle”, and “Lower” indicated on the horizontal axis in FIG. 11 represent the positions of semiconductor wafers W in the processing container 34. “Upper” indicates semiconductor wafers W on the Z1 side, “Lower” indicates semiconductor wafers W installed on the Z2 side, and “Middle” indicates semiconductor wafers W installed at an intermediate position therebetween. As shown in FIG. 11, in the substrate processing apparatus of the present embodiment, the in-plane uniformity of silicon films formed on semiconductor wafers W is ±3.08% at “Upper”, ±2.95% at “Middle”, and ±2.87% at “Middle”, and thus low and uniform as a whole. Accordingly, when silicon films are formed in the same batch, it is possible to use all the semiconductor wafers W in a subsequent process, and thus it is possible to reduce the cost of manufacturing semiconductor devices.

### (Modification of Semiconductor Film Formation Method)

Next, a modification of a film formation method of a semiconductor device in the present embodiment will be described with reference to FIGS. 12 to 14.

First, as illustrated in FIG. 12, a semiconductor wafer W having a silicon oxide film 202 formed on a surface of a silicon substrate 201 is provided. The silicon oxide film 202 is formed by thermally oxidizing silicon on the surface of the silicon substrate 201, but may be formed by a film formation method such as sputtering or CVD method.

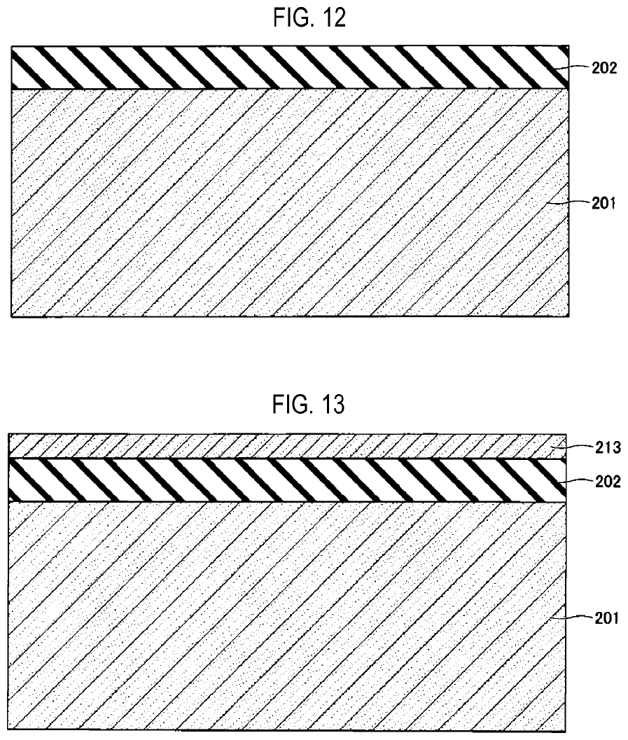

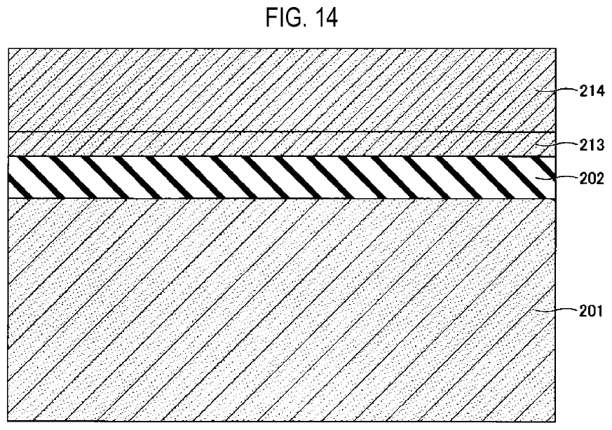

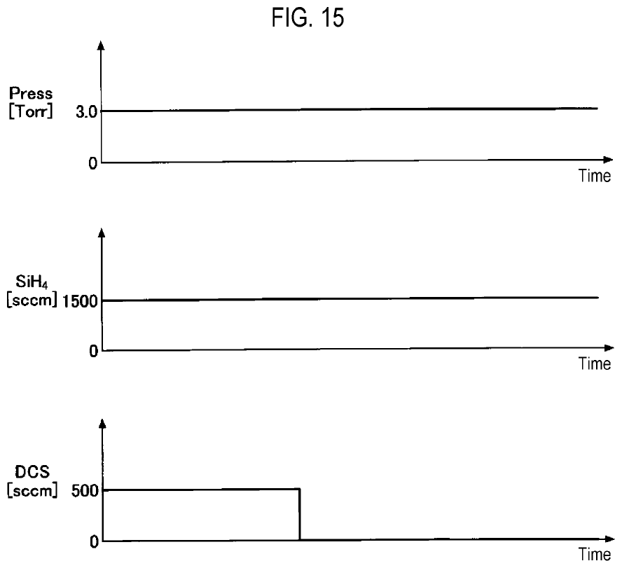

Next, as illustrated in FIG. 13, a first silicon film 213 having a film thickness of 1 to 2 nm is formed on the silicon oxide film 202 of the semiconductor wafer W using the substrate processing apparatus 10 of the present embodiment. Specifically, as illustrated in FIG. 15, the first silicon film 213 is formed by simultaneously supplying monosilane as the first raw material gas at 1,500 sccm and dichlorosilane as the second raw material gas at 500 sccm. At this time, the gas pressure inside the processing container is set to 3.0 Torr.

Next, as illustrated in FIG. 14, a second silicon film 214 having a film thickness of, for example, 10 to 20 nm is formed on the first silicon film 213 using the substrate processing apparatus 10 of the present embodiment. Specifically, as shown in FIG. 15, the second silicon film 214 is formed by stopping the supply of the dichlorosilane as the second raw material gas, and supplying the monosilane as the first raw material gas at 1,500 sccm. At this time, the gas pressure inside the processing container is set to 3.0 Torr.

According to the substrate processing apparatus disclosed herein, it is possible to form a film with good in-plane uniformity in film thickness between substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a processing container configured to accommodate a plurality of substrates therein;
a gas supply configured to supply a first raw material gas of a compound containing Si or Ge and H and a second raw material gas of a compound containing Si or Ge and a halogen element into the processing container; and
an exhauster configured to evacuate an inside of the processing container,
wherein the gas supply has a dispersion nozzle provided with a plurality of gas holes for discharging the first raw material gas and the second raw material gas, and
the substrate processing apparatus further comprises a heater configured to heat the first raw material gas and the second raw material gas in the dispersion nozzle.

2. The substrate processing apparatus of claim 1, wherein the gas supply is connected to a raw material gas mixer, and a mixture gas obtained by mixing the first raw material gas and the second raw material gas in the raw material gas mixer is supplied into the processing container.

3. The substrate processing apparatus of claim 1, wherein the plurality of substrates are arranged in a direction perpendicular to surfaces of the plurality of substrates, and
the dispersion nozzle extends in the direction perpendicular to the surfaces of the plurality of substrates, and is provided with a plurality of gas holes.

4. The substrate processing apparatus of claim 1, wherein the first raw material gas and the second raw material gas are discharged parallel to the substrates from the plurality of gas holes in the dispersion nozzle, and are exhausted from an opening formed at a position facing the dispersion nozzle with the substrates interposed therebetween.

5. The substrate processing apparatus of claim 1, wherein the first raw material gas is SiH₄ or Si₂H₆, and
the second raw material gas includes any one of SiCl₄, SiHCl₃, SiH₂Cl₂, SiH₃Cl, and Si₂Cl₆.

6. The substrate processing apparatus of claim 1, wherein the first raw material gas is SiH₄, and
the second raw material gas is SiH₂Cl₂.

7. The substrate processing apparatus of claim 1, wherein the heater also heats the substrates.
